(19) United States
(12) Patent Application Publication
(10) Pub. No.: US 2009/0308445 A1
(43) Pub. Date: Dec. 17, 2009

(54) PHOTOVOLTAIC CELL AND PHOTOVOLTAIC CELL SUBSTRATE

(75) Inventor: Emmanuelle PETER, Paris (FR)

Correspondence Address: OBLON, SPIVAK, MCCLELLAND MAIER & NEUSTADT, L.L.P., 1940 DUKE STREET, ALEXANDRIA, VA, 22314, US

(73) Assignee: SAINT GOBAIN GLASS FRANCE, Courbevoie (FR)

(21) Appl. No.: 12/171,653

(22) Filed: Jul. 11, 2008

(30) Foreign Application Priority Data
Jun. 11, 2008 (FR) 0853870

(51) Int. Cl. H01L 31/00; B05D 5/12

(52) U.S. Cl. 136/256; 427/74

(57) ABSTRACT

Method of fabricating a transparent electrode based on zinc oxide, possibly doped, characterized in that a layer based on zinc oxide is deposited on at least one of the faces of a substrate or on at least one layer in contact with one of the faces of said substrate, and in that this layer is subjected to a controlled oxidation so as to over-oxidize a portion of the surface of said layer to a fraction of its thickness.

The invention relates to a front face substrate for a photovoltaic cell, notably a transparent glass substrate, and a photovoltaic cell incorporating such a substrate.

In a photovoltaic cell, a photovoltaic system with photovoltaic material that produces electrical energy under the effect of an incident radiation is positioned between a rear face substrate and a front face substrate, this front face substrate being the first substrate that is passed through by the incident radiation before it reaches the photovoltaic material.

In the photovoltaic cell, the front face substrate usually comprises, below a main surface facing the photovoltaic material, a transparent electrode coating in electrical contact with the photovoltaic material positioned underneath when it is assumed that the main direction of arrival of the incident radiation is from above.

This front face electrode coating thus generally forms the negative (or hole-collecting) terminal of the solar cell. Obviously, the solar cell also comprises on the rear face substrate an electrode coating which then forms the positive (or electron-collecting) terminal of the solar cell, but generally, the electrode coating of the rear face substrate is not transparent.

The material normally used for the transparent electrode coating of the front face substrate is generally a material based on transparent conductive oxide (TCO), such as, for example, a material based on indium and tin oxide (ITO), or based on zinc oxide doped with aluminium (ZnO:Al) or doped with boron (ZnO:B), or even based on tin oxide doped with fluorine (SnO₂:F), or even mixed indium and zinc oxide (IZO). These materials are deposited by chemical process, such as, for example, by chemical vapour deposition (CVD), possibly plasma-enhanced (PECVD), or by physical process, such as, for example, by vacuum deposition by cathode sputtering, possibly assisted by magnetic field (magnetron).

However, to obtain the desired electrical conduction, or rather the desired low resistance, the TCO-based electrode coating must be deposited to a relatively great physical thickness, of the order of 500 to 1000 nm and even sometimes more, which is expensive given the cost of these materials when they are deposited in thin layers.

When the deposition method requires an addition of heat, this further increases the production cost.

Another major drawback of the TCO-based electrode coatings lies in the fact that, for a chosen material, its physical thickness is always a trade-off between the electrical conduction ultimately obtained and the transparency ultimately obtained, because the greater the physical thickness is, the stronger the conductivity will be but the weaker the transparency will be, and conversely, the smaller the physical thickness is, the greater the transparency will be, but the weaker the conductivity will be.

It is therefore not possible with TCO-based electrode coatings to independently optimize the conductivity of the electrode coating and its transparency.

However, this solution can be further enhanced.

The prior art also knows the American patent U.S. Pat. No. 6,169,246 which relates to a photovoltaic cell with cadmium-based absorbent photovoltaic material, said cell comprising a transparent glass front face substrate comprising on a main surface a transparent electrode coating consisting of a transparent conductive oxide TCO.

According to this document, above the TCO electrode coating and below the photovoltaic material, there is inserted a buffer layer made of zinc stannate which is neither part of the TCO electrode coating nor part of the photovoltaic material. This layer also has the drawback of being very difficult to deposit by magnetron sputtering techniques, the target incorporating this material being naturally electrically insulating.

The present invention therefore aims to overcome the drawbacks of the prior art solutions by proposing a method of producing a transparent conductive electrode without adding an output work adaptation layer.

One important aim of the invention is to enable the transfer of charge between the electrode coating and the photovoltaic material, in particular cadmium-based, to be easily controlled and the efficiency of the cell to be able consequently to be enhanced.

Another important aim is also to produce a transparent electrode coating based on thin layers which is simple to produce and as inexpensive as possible to manufacture industrially.

The subject of the invention is thus a method of fabricating a transparent electrode based on zinc oxide, possibly doped, which is characterized in that a layer based on zinc oxide is deposited on at least one of the faces of a substrate or on at least one layer in contact with one of the faces of said substrate, and in that this layer is subjected to a controlled oxidation so as to over-oxidize a portion of the surface of said layer to a fraction of its thickness.

In a preferred variant of the invention, the transparent conductive layer is based on zinc oxide, over-stoichiometric, possibly doped.

Its physical thickness is preferably between 400 and 1400 nm. The transparent conductive layer is possibly deposited, according to an embodiment variant of the invention, on an anchoring layer, designed to favour the appropriate crystalline orientation of the conductive layer deposited above). This anchoring layer is notably based on mixed zinc and tin oxide or based on mixed indium and tin oxide (ITO).

In another preferred variant of the invention, the transparent conductive layer is deposited on a layer presenting a chemical barrier to diffusion, and in particular to the diffusion of sodium originating from the substrate, then protecting the coating forming the electrode, and more particularly the conductive layer, notably in a possible heat treatment process, notably a hardening process, the physical thickness of this barrier layer being between 20 and 50 nm.

Thus, the electrode coating should be transparent. It should thus offer, when deposited on the substrate, in the range of wavelengths between 300 and 1200 nm, a minimum average light transmission of 656, even 75%, and preferably even 85% or even more notably at least 90%.

If the front face substrate is to be subjected to a heat treatment, notably hardening, after the deposition of the thin layers and before its incorporation in the photovoltaic cell, it is quite possible that, before the heat treatment, the coated substrate of the stack acting as electrode coating will be not very transparent. It may, for example, have, before this heat treatment, a light transmission in the visible spectrum of less than 65%, even less than 50%.

The important thing is that the electrode coating is transparent before heat transparent so that it offers, after heat treatment, in the range of wavelengths between 300 and 1200 nm, a minimum average light transmission of 65%, even 75% and preferably even 85% or more notably at least 90%.

Thus, it is then possible to choose the transparent electrode thickness according to the desired output work.

Moreover, in the context of the invention, the stack does not absolutely offer the best possible light transmission, but offers the best possible light transmission in the context of the inventive photovoltaic cell, that is, in the quantum efficiency range QE of the photovoltaic material concerned.

It should be recalled here that the quantum efficiency QE is, in a known manner, the expression of the probability (between 0 and 1) that an incident photon with a wavelength along the X-axis will be transformed into an electron-hole pair.

The maximum absorption wavelength λm, that is, the wavelength at which the quantum efficiency is maximum, is of the order of 640 nm for cadmium.

The transparent conductive layer is, preferably, deposited in a crystalline form or in an amorphous form but one that becomes crystallized after heat treatment, on a thin dielectric layer which (then called “anchoring layer” because it favours the appropriate crystalline orientation of the metallic layer deposited above).

The transparent conductive layer is thus, preferably, deposited above, even directly on, an oxide-based anchoring layer, notably based on zinc oxide or based on mixed zinc and tin oxide, possibly doped, possibly with aluminium (doping should be understood in the usual way to mean a presence of the element in a quantity of 0.1 to 10% by molar weight of metallic element in the layer and the expression “based on” should be understood in the normal way to mean a layer mostly comprising the material; the expression “based on” thus covers the doping of this material with another), or based on zinc oxide and tin oxide, possibly one and/or the other doped.

The physical (or real) thickness of the anchoring layer is preferably between 2 and 30 nm and preferably even between 3 and 20 nm.

This anchoring layer is a material which preferably offers a resistivity p (defined by the product of the resistance per square of the layer by its thickness) such that 0.2 mΩ·cm<p<200Ω·cm.

The stack is generally obtained by a succession of depositions performed by a technique using vacuum, such as cathodic sputtering, possibly assisted by magnetic field.

The substrate can comprise a coating based on photovoltaic material, notably based on cadmium, above the electrode coating opposite to the front face substrate.

A preferred front face substrate structure according to the invention is thus of the type: substrate/electrode coating/photovoltaic material.

There is thus a particular interest, when the photovoltaic material is based on cadmium, in choosing an architectural glazing for vehicle or building applications and resistant to the hardening heat treatment, called “hardenable” or “to be hardened”.

All the layers of the electrode coating are, preferably, deposited by a vacuum deposition technique, but there is no reason why the first layer or layers of the stack should not be deposited by another technique, for example by a thermal decomposition technique of pyrolysis type or by CVD, possibly under vacuum.

Advantageously, furthermore, the electrode coating according to the invention can perfectly well be used as rear face electrode coating, particularly when there is a desire for at least a small part of the incident radiation to pass completely through the photovoltaic cell.

The details and advantageous characteristics of the invention will become apparent from the following nonlimiting examples, illustrated using the appended figures:

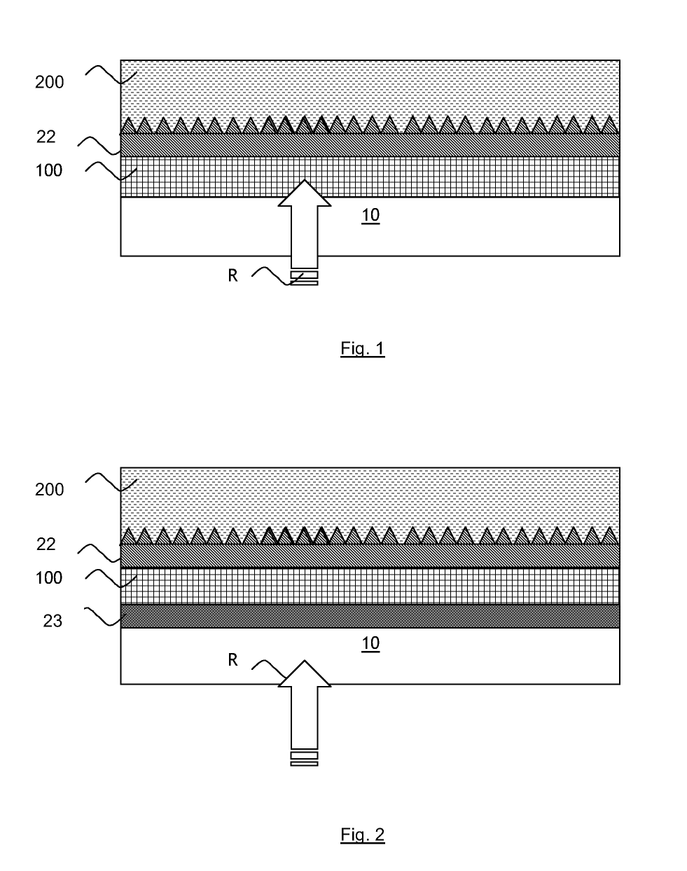

FIG. 1 illustrates a front face substrate of a solar cell according to a first embodiment of the invention, coated with an electrode coating of transparent conductive oxide;

FIG. 2 illustrates a front face substrate of a solar cell according to a second embodiment of the invention, coated with an electrode coating of transparent conductive oxide and incorporating an anchoring layer;

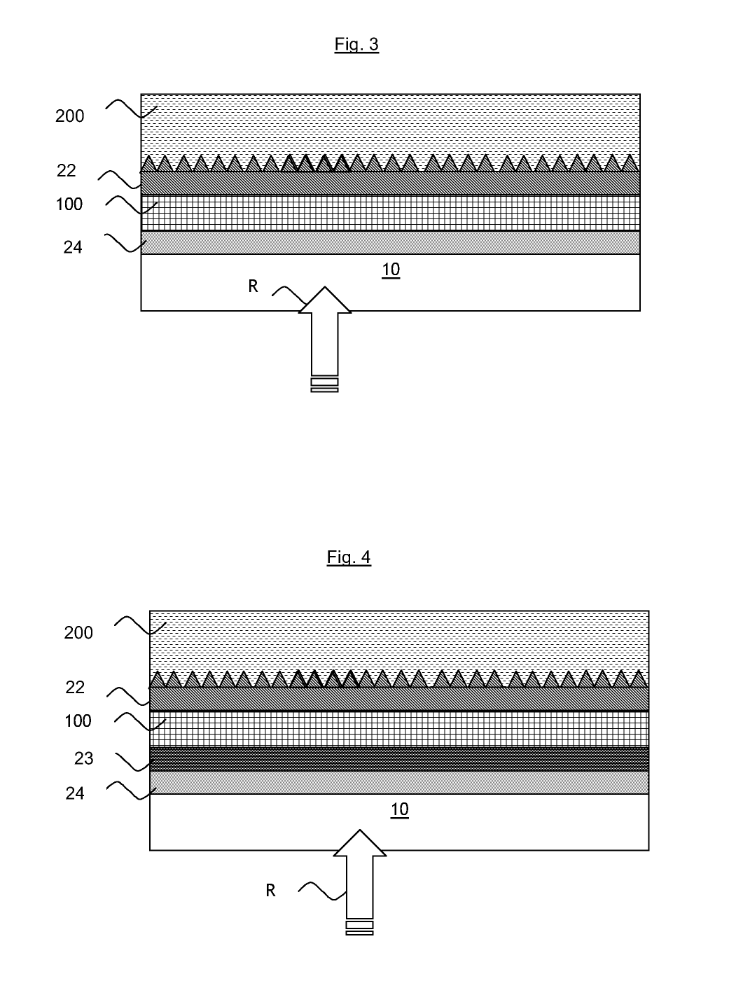

FIG. 3 illustrates a front face substrate of a solar cell according to a third embodiment of the invention, coated with an electrode coating of transparent conductive oxide and incorporating an alkali-barrier layer;

FIG. 4 illustrates a front face substrate of a solar cell according to the invention according to a fourth embodiment of the invention, coated with an electrode coating of transparent conductive oxide and incorporating both an anchoring layer and an alkali-barrier layer;

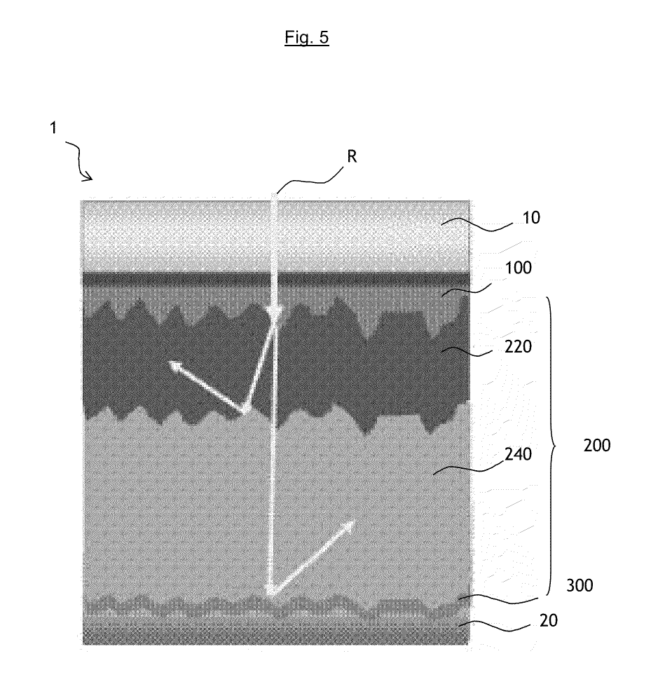

FIG. 5 illustrates a cross-sectional diagram of a photovoltaic cell.

In FIGS. 1, 2, 3, 4 and 5, the proportions between the thicknesses of the various coatings, layers, materials are not strictly observed in order to facilitate reading.

FIG. 1 illustrates a front face substrate 10 of a photovoltaic cell according to the invention with absorbent photovoltaic material 200, said substrate 10 comprising, on a main surface, a transparent electrode coating 100 consisting of a TCO, also called transparent conductive layer.

The front face substrate 10 is positioned in the photovoltaic cell so that the front face substrate 10 is the first substrate to be passed through by the incident radiation R, before reaching the photovoltaic material 200.

FIG. 2 differs from FIG. 1 in that an anchoring layer 23 is inserted between the conductive layer 100 and the substrate 10.

FIG. 3 differs from FIG. 1 in that an alkali-barrier layer 24 is inserted between the conductive layer 100 and the substrate 10.

FIG. 4 incorporates the arrangements of the solutions presented in FIGS. 2 and 3, namely that the transparent conductive layer is deposited on an anchoring layer 23, which is itself deposited on an alkali-barrier layer 24.

The conductive layer 100, with a thickness of between 400 and 1400 nm, is based on aluminium-doped zinc oxide (ZnO:Al), this layer is deposited on an anchoring layer based on mixed zinc and tin oxide, in a thickness of between 2 and 30 nm and preferably even between 3 and 20 nm, for example 7 nm, which is itself deposited on an alkali-barrier layer 24, for example based on a dielectric material, notably of nitrides, oxides or oxynitrides of silicon, or of nitrides, oxides or oxynitrides of aluminium, used alone or in a mixture, its thickness is between 30 and 50 nm.

After having deposited these layers, the terminal layer based on zinc oxide is subjected to an over-oxidation. To this end, in the deposition enclosure (in at least one chamber of the magnetron), the quantity of oxygen introduced during the zinc oxide deposition phase is varied. An oxygen-concentration gradient in the thickness of the deposited layer is thus created.

This oxygen-concentration gradient in the layer of Zno is delimited in the figures by the item 22. It is then possible, by modifying the oxygen-addition parameters, to control the level of oxidation and the thickness of over-stoichiometric ZnO in order to control the output work of the electrode.

The test sample is as follows:

V extra light (3 mm)/Si₃N₄ (40 nm)/ZnO: Al (500 nm),

A table is given below which demonstrates, for the above sample, the influence of the quantity of O₂ introduced on the output work of the cell.

| Ar flux (sccm) | O₂/Ar flux (10%) | Output work (eV) |
|---|---|---|
| 150 | 0 | 4.5 |
| 150 | 3 | 4.6 |
| 150 | 8 | 4.7 |
| 150 | 20 | 4.9 |

FIG. 5 illustrates a photovoltaic cell 1 in cross section, provided with a front face substrate 10 according to the invention, through which an incident ray R penetrates, and a rear face substrate 20.

The photovoltaic material 200, for example of cadmium, is located between these two substrates. It comprises a layer of n-doped semiconductive material 220 and a layer of p-doped semiconductive material 240, which produce the electric current. The electrode coatings 100, 300 respectively inserted between, on the one hand, the front face substrate 10 and the layer of n-doped semiconductive material 220 and on the other hand between the layer of p-doped semiconductive material 240 and the rear face substrate 20 complete the electrical structure.

The electrode coating 300 can be based on silver or aluminium, or can also consist of a stack of thin layers comprising at least one metallic functional layer and conforming to the present invention.

The present invention is described hereinabove by way of example. It should be understood that those skilled in the art will be able to produce different variants of the invention without in any way departing from the framework of the patent as defined by the claims.

1. Method of fabricating a transparent electrode based on zinc oxide, possibly doped, characterized in that a layer based on zinc oxide is deposited on at least one of the faces of a substrate or on at least one layer in contact with one of the faces of said substrate, and in that this layer is subjected to a controlled oxidation so as to over-oxidize a portion of the surface of said layer to a fraction of its thickness.

2. Fabrication method according to claim 1, characterized in that the controlled oxidation is provoked by the addition of oxygen during the zinc oxide deposition phase.

3. Fabrication method according to any one of the preceding claims, characterized in that the layer based on zinc oxide is deposited on a barrier layer.

4. Fabrication method according to any one of claims 1 to 3, characterized in that the layer based on zinc oxide is deposited on an anchoring layer.

5. Photovoltaic cell (1) with absorbent photovoltaic material, notably cadmium based, said cell comprising a front face substrate (10), notably a transparent glass substrate, comprising, on a main surface, a transparent electrode coating (100) consisting of a stack of thin layers comprising at least one transparent conductive layer obtained by the method according to any one of claims 1 to 4.

6. Cell according to claim 5, characterized in that it comprises between the substrate (10) and the transparent conductive layer (100) at least one anchoring layer (23).

7. Photovoltaic cell (1) according to claim 6, characterized in that the anchoring layer (23) is zinc oxide based or mixed zinc and tin oxide based or mixed indium and tin oxide based (ITO).

8. Photovoltaic cell (1) according to claim 7, characterized in that it comprises between the substrate (10) and the transparent conductive layer (100) at least one alkali-barrier layer (24).

9. Photovoltaic cell (1) according to claim 8, characterized in that the alkali-barrier layer (24) is based on a dielectric material, notably of nitrides, oxides or oxynitrides of silicon, or of nitrides, oxides or oxynitrides of aluminium, used alone or in a zinc oxide mixture or based on mixed zinc and tin oxide.

10. Substrate (10) coated with a stack of thin layers for a photovoltaic cell (1) according to any one of claims 5 to 9, notably substrate for architectural glazing, notably substrate for architectural glazing that can be hardened or is to be hardened.

11. Use of a substrate coated with a stack of thin layers to produce a front face substrate (10) for a photovoltaic cell (1), in particular a photovoltaic cell (1) according to any one of claims 5 to 9, said substrate comprising a transparent electrode coating (100) consisting of a stack of thin layers comprising at least one transparent conductive layer, notably zinc oxide based.

12. Use according to the preceding claim in which the substrate (10) comprising the electrode coating (100) is a substrate for architectural glazing, notably a substrate for architectural glazing that can be hardened or is to be hardened.
